(19) United States
(12) Patent Application Publication
(10) Pub. No.: US 2023/0308079 A1
(43) Pub. Date: Sep. 28, 2023

(54) ACOUSTIC WAVE DEVICE

(71) Applicant: Murata Manufacturing Co., Ltd., Nagaokakyo-shi (JP)

(72) Inventor: Katsuya DAIMON, Nagaokakyo-shi (JP)

(21) Appl. No.: 18/200,012

(22) Filed: May 22, 2023

Related U.S. Application Data
(63) Continuation of application No. PCT/JP2022/000840, filed on Jan. 13, 2022.

(30) Foreign Application Priority Data
Jan. 19, 2021 (JP) 2021-006432

(51) Int. Cl. H03H 9/25; H03H 9/02; H03H 9/145

(52) U.S. Cl. CPC H03H 9/25; H03H 9/02559; H03H 9/02637; H03H 9/02866; H03H 9/145

(57) ABSTRACT

An acoustic wave device includes a piezoelectric substrate including a piezoelectric layer, an IDT electrode provided on the piezoelectric substrate and including electrode fingers, and a dielectric film between the piezoelectric substrate and the IDT electrode. A portion of the IDT electrode in which the electrode fingers overlap with each other when seen in a propagation direction of an acoustic wave is an intersecting range. The intersecting range includes a central range and a first range and a second range sandwiching the central range in an electrode finger extending direction. Permittivity and density of the dielectric film are lower than that of the piezoelectric layer. When seen in plan view, the dielectric film is provided at a portion overlapping with the central range, and not provided at a portion overlapping with one of the first range and the second range.

### CROSS REFERENCE TO RELATED APPLICATIONS

This application claims the benefit of priority to Japanese Pat. Application No. 2021-006432 filed on Jan. 19, 2021 and is a Continuation Application of PCT Application No. PCT/JP2022/000840 filed on Jan. 13, 2022. The entire contents of each application are hereby incorporated herein by reference.

### BACKGROUND OF THE INVENTION

### 1. Field of the Invention

The present invention relates to an acoustic wave device.

### 2. Description of the Related Art

Conventionally, acoustic wave devices are widely used for filters of cellular phones or the like. Japanese Pat. No. 5221616 described below discloses one example of an acoustic wave device. In this acoustic wave device, an interdigital transducer (IDT) electrode is provided on a piezoelectric substrate. In a direction in which a plurality of electrode fingers of the IDT electrode extend, a plurality of ranges having different acoustic velocities are arranged. Specifically, a low acoustic velocity range is located at an outer side portion of a central range, and a high acoustic velocity range is located at an outer side portion of the low acoustic velocity range. As a result, a piston mode is achieved, thus a transverse mode is suppressed.

A band-shaped dielectric film is provided to the central range described above. The dielectric film covers the plurality of electrode fingers in the central range. Therefore, the acoustic velocity in the central range is increased, which causes a difference in acoustic velocity between the central range and the low acoustic velocity range.

### SUMMARY OF THE INVENTION

However, in the configuration described in Japanese Pat. No. 5221616, where the central range of the electrode fingers are covered by the dielectric film, the dielectric film which can increase the acoustic velocity in the central range is limited to a silicon nitride film or the like, and it is known that the acoustic velocity is lowered when a silicon oxide film or the like is used. As described above, a material which can be used to increase the acoustic velocity for achieving a piston mode is limited.

Preferred embodiments of the present invention provide acoustic wave devices each capable of suppressing a transverse mode while improving a degree of freedom in material.

An acoustic wave device according to a preferred embodiment of the present invention includes a piezoelectric substrate including a piezoelectric layer, an IDT electrode provided on the piezoelectric substrate and including a plurality of electrode fingers, and a dielectric film between the piezoelectric substrate and the IDT electrode. A portion of the IDT electrode in which the electrode fingers overlap with each other when seen in a propagation direction of an acoustic wave is an intersecting range, the electrode fingers being adjacent to each other. When a direction in which the plurality of electrode fingers extend is an electrode finger extending direction, the intersecting range includes a central range located at a center in the electrode finger extending direction, and a first range and a second range sandwiching the central range in the electrode finger extending direction. Permittivity and density of the dielectric film are lower than permittivity and density of the piezoelectric layer. When seen in plan view, the dielectric film is provided at a portion overlapping with the central range, and not provided at a portion overlapping with one of the first range and the second range.

According to acoustic wave devices of preferred embodiments of the present invention, the transverse mode can be suppressed while the degree of freedom in material is improved.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a plan view of an acoustic wave device according to a first preferred embodiment of the present invention.

FIG. 2 is a sectional view taken along a line I-I in FIG. 1.

FIG. 3 is a plan view of an acoustic wave device according to a second comparative example.

FIG. 4 is a diagram illustrating a relationship between a thickness of a dielectric film and an acoustic velocity in a central range of an IDT electrode.

FIG. 5 is a diagram illustrating impedance frequency characteristics in the central range and a first range in the first preferred embodiment of the present invention and the second comparative example.

FIG. 6 is a front sectional view partially illustrating an acoustic wave device according to a first modification of the first preferred embodiment of the present invention.

FIG. 7 is a front sectional view partially illustrating an acoustic wave device according to a second modification of the first preferred embodiment of the present invention.

FIG. 8 is a diagram illustrating a relationship between an acoustic velocity ratio Ve/Vc and a thickness and density of the dielectric film.

FIG. 9 is a diagram illustrating a relationship between the acoustic velocity ratio Ve/Vc and the thickness and Young’s modulus of the dielectric film.

FIG. 10 is a diagram illustrating a relationship between the acoustic velocity ratio Ve/Vc and the thickness and permittivity of the dielectric film.

### DETAILED DESCRIPTION OF THE PREFERRED EMBODIMENTS

Hereinafter, detailed preferred embodiments of the present invention are described with reference to the drawings to reveal the present invention.

Note that the preferred embodiments described herein are merely examples, and it should be noted that partial replacement and combination of configurations are possible between different preferred embodiments.

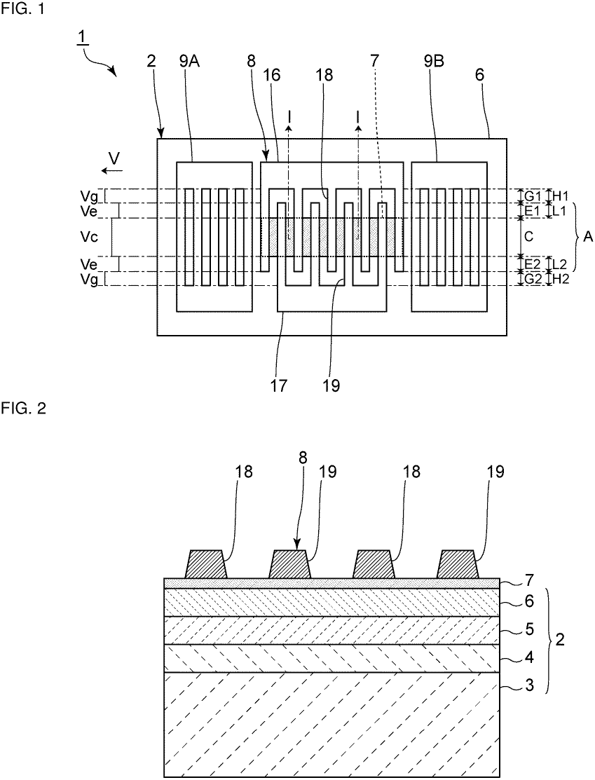

FIG. 1 is a plan view of an acoustic wave device according to a first preferred embodiment of the present invention. FIG. 2 is a sectional view taken along a line I-I in FIG. 1. Note that, in the plan views in FIG. 1 and other than FIG. 1, a dielectric film described later is indicated by hatching.

In an acoustic wave device 1 illustrated in FIG. 1, a piston mode is achieved, and thus a transverse mode is suppressed. The acoustic wave device 1 includes a piezoelectric substrate 2. As illustrated in FIG. 2, the piezoelectric substrate 2 is a multilayer substrate including a piezoelectric layer 6. An IDT electrode 8 is provided on the piezoelectric layer 6. Note that a dielectric film 7 is provided between the piezoelectric layer 6 and the IDT electrode 8.

By the IDT electrode 8 being applied with alternating-current voltage, an acoustic wave is excited. As illustrated in FIG. 1, a reflector 9A and a reflector 9B as a pair are provided on the piezoelectric layer 6 on the respective sides in a propagation direction of an acoustic wave. As described above, the acoustic wave device 1 of this preferred embodiment is a surface acoustic wave resonator. Note that the acoustic wave device according to the present invention is not limited to the acoustic wave resonator, but may be a filter device or a multiplexer having a plurality of acoustic wave resonators.

The IDT electrode 8 includes a plurality of electrode fingers. The IDT electrode 8 has a central range C, a first range E1, a second range E2, a first gap range G1, and a second gap range G2. Each of the first range E1 and the second range E2 includes tip-end portions of the plurality of electrode fingers. By making acoustic velocities in the respective ranges different from each other, a piston mode is achieved.

Unique features of this preferred embodiment include that the acoustic wave device 1 has the following configurations. 1) Permittivity and density of the dielectric film 7 is lower than permittivity and density of the piezoelectric layer 6. 2) The dielectric film 7 is provided between the piezoelectric substrate 2 and the IDT electrode 8, and when seen in plan view, provided at a portion overlapping with the central range C, and not provided at a portion overlapping with one of the first range E1 and the second range E2. Therefore, not only when a limited type of dielectrics such as silicon nitride is used as the dielectric film 7, but also when another dielectric is used, the acoustic velocity in the central range C can be increased. Thus, the acoustic velocities in the first range E1 and the second range E2 can easily be made lower than the acoustic velocity in the central range C, and a piston mode can be achieved. As a result, a transverse mode can be suppressed while a degree of freedom in material is improved. Details regarding this will be described below together with details of configurations of this preferred embodiment.

As illustrated in FIG. 2, the piezoelectric substrate 2 includes a support substrate 3, a high acoustic velocity film 4 as a high acoustic velocity material layer, a low acoustic velocity film 5, and the piezoelectric layer 6. More specifically, the high acoustic velocity film 4 is provided on the support substrate 3. The low acoustic velocity film 5 is provided on the high acoustic velocity film 4. The piezoelectric layer 6 is provided on the low acoustic velocity film 5.

In this preferred embodiment, the piezoelectric layer 6 is a lithium tantalate layer. Meanwhile, the dielectric film 7 is a silicon oxide film. Therefore, the permittivity and the density of the dielectric film 7 is lower than the permittivity and the density of the piezoelectric layer 6. Note that the material of the piezoelectric layer 6 is not limited to the above, but for example, lithium niobate, zinc oxide, aluminum nitride, crystal, lead zirconate titanate (PZT), or the like can be used. The material of the dielectric film 7 is not limited to the above, but for example, silicon nitride, aluminum oxide, or the like can be used. They may be any material as long as the dielectric film 7 has permittivity and density lower than those of the piezoelectric layer 6.

The low acoustic velocity film 5 is a relatively low acoustic velocity film. More specifically, an acoustic velocity of a bulk wave which propagates in the low acoustic velocity film 5 is lower than an acoustic velocity of a bulk wave which propagates in the piezoelectric layer 6. As a material of the low acoustic velocity film 5, for example, a material whose major constituent is glass, silicon oxide, silicon oxynitride, lithium oxide, tantalum pentoxide, or a chemical compound in which fluorine, carbon, and boron are added to silicon oxide can be used.

The high acoustic velocity material layer is a relatively high acoustic velocity material. In this preferred embodiment, the high acoustic velocity material layer is the high acoustic velocity film 4. An acoustic velocity of a bulk wave which propagates in the high acoustic velocity material layer is higher than an acoustic velocity of an acoustic wave which propagates in the piezoelectric layer 6. As the material of the high acoustic velocity film 4, a medium with a major constituent such as silicon, aluminum oxide, silicon carbide, silicon nitride, silicon oxynitride, sapphire, lithium tantalate, lithium niobate, crystal, alumina, zirconia, cordierite, mullite, steatite, forsterite, magnesia, a diamond-like carbon (DLC) film, or diamond can be used.

As the material of the support substrate 3, for example, a piezoelectric material (for example, aluminum oxide, lithium tantalate, lithium niobate, and crystal), various ceramics (for example, alumina, sapphire, magnesia, silicon nitride, aluminum nitride, silicon carbide, zirconia, cordierite, mullite, steatite, and forsterite), a dielectric (for example, diamond and glass), a semiconductor (for example, silicon and gallium nitride), a resin, or the like can be used.

As illustrated in FIG. 1, the IDT electrode 8 includes a first busbar 16, a second busbar 17, a plurality of first electrode fingers 18, and a plurality of second electrode fingers 19. The first busbar 16 and the second busbar 17 are opposed to each other. Each of the plurality of first electrode fingers 18 has one end connected to the first busbar 16. Each of the plurality of second electrode fingers 19 has one end connected to the second busbar 17. The plurality of first electrode fingers 18 and the plurality of second electrode fingers 19 interdigitate with each other. As illustrated in FIG. 2, the dielectric film 7 is provided between a surface of the IDT electrode 8 on the piezoelectric layer 6 side and the piezoelectric layer 6. Note that it is not always necessary that the dielectric film 7 is provided between the first electrode finger 18 and the second electrode finger 19.

Here, a direction in which the plurality of first electrode fingers 18 and the plurality of second electrode fingers 19 extend is an electrode finger extending direction. In this preferred embodiment, the electrode finger extending direction is orthogonal to a propagation direction of an acoustic wave. In the IDT electrode 8, when seen in the propagation direction of the acoustic wave, a portion where the first electrode finger 18 and the second electrode finger 19 next to each other overlap with each other is an intersecting range A. The intersecting range A includes the central range C, the first range E1, and the second range E2. The central range C is located at a center side portion of the intersecting range A in the electrode finger extending direction. The first range E1 and the second range E2 are located to sandwich the central range C in the electrode finger extending direction. More specifically, the first range E1 is located on the first busbar 16 side of the central range C. The second range E2 is located on the second busbar 17 side of the central range C. Moreover, the first gap range G1 is located between the first range E1 and the first busbar 16. The second gap range G2 is located between the second range E2 and the second busbar 17.

The IDT electrode 8 has a multilayer structure, and includes a main electrode layer, an adhesion layer, and a protection layer. The adhesion layer, the main electrode layer, and the protection layer are laminated in this order from the piezoelectric layer 6 side. Herein, the main electrode layer is a layer occupying a ratio of about 50% or larger the mass of the IDT electrode 8. In this preferred embodiment, both of the adhesion layer and the protection layer are Ti layers, and the main electrode layer is an Al layer. Note that the material of the IDT electrode 8 is not limited to the above. Alternatively, the IDT electrode 8 may be defined by only the main electrode layer. For the reflector 9A and the reflector 9B, a material similar to the material of the IDT electrode 8 may be used.

In the acoustic wave device 1, a plurality of ranges where acoustic velocities are different from each other are arranged in the electrode finger extending direction. Specifically, from the center in the electrode finger extending direction, the central range C, low acoustic velocity ranges L1 and L2, and high acoustic velocity ranges H1 and H2 are arranged in this order. Note that the low acoustic velocity ranges L1 and L2 are ranges where the acoustic velocity therein is lower than the acoustic velocity in the central range C. The low acoustic velocity range L1 is in the first range E1. The low acoustic velocity range L2 is in the second range E2. The high acoustic velocity ranges H1 and H2 are ranges where the acoustic velocity therein is higher than the acoustic velocity in the central range C. The high acoustic velocity range H1 is in the first gap range G1. The high acoustic velocity range H2 is in the second gap range G2.

In this preferred embodiment, the dielectric film 7 is provided between the piezoelectric layer 6 and the IDT electrode 8 at the portion overlapping with the central range C in plan view. On the other hand, the dielectric film 7 is not provided at the portion overlapping with one of the first range E1 and the second range E2 in plan view. Therefore, the acoustic velocity in the central range C is higher than the acoustic velocity in the first range E1 and the second range E2. That is, the acoustic velocity in the first range E1 and the second range E2 is lower than the acoustic velocity in the central range C. On the other hand, in the first gap range G1, only the first electrode finger 18 among the first electrode finger 18 and the second electrode finger 19 is provided. Therefore, the acoustic velocity in the first gap range G1 is higher than the acoustic velocity in the central range C. Similarly, in the second gap range G2, only the second electrode finger 19 among the first electrode finger 18 and the second electrode finger 19 is provided. Therefore, the acoustic velocity in the second gap range G2 is higher than the acoustic velocity in the central range C.

Here, assuming that the acoustic velocity in the central range C is Vc, the acoustic velocity in the first range E1 and the second range E2 is Ve, and the acoustic velocity in the first gap range G1 and the second gap range G2 is Vg, a relationship between the respective acoustic velocities is Vg > Vc > Ve. Note that in a portion of FIG. 1 indicating the relationship of the acoustic velocities, as indicated by an arrow V, the acoustic velocity increases as a line indicative of the magnitude of the acoustic velocity is located more left. The central range C, the low acoustic velocity ranges L1 and L2, and the high acoustic velocity ranges H1 and H2 are arranged in this order from the center in the electrode finger extending direction. Therefore, a piston mode is achieved.

In this disclosure, as described above, the acoustic velocity in the central range C can be increased by the dielectric film 7 being provided between the piezoelectric layer 6 and the IDT electrode 8 at the portion overlapping with the central range C in plan view. Details regarding this is described below.

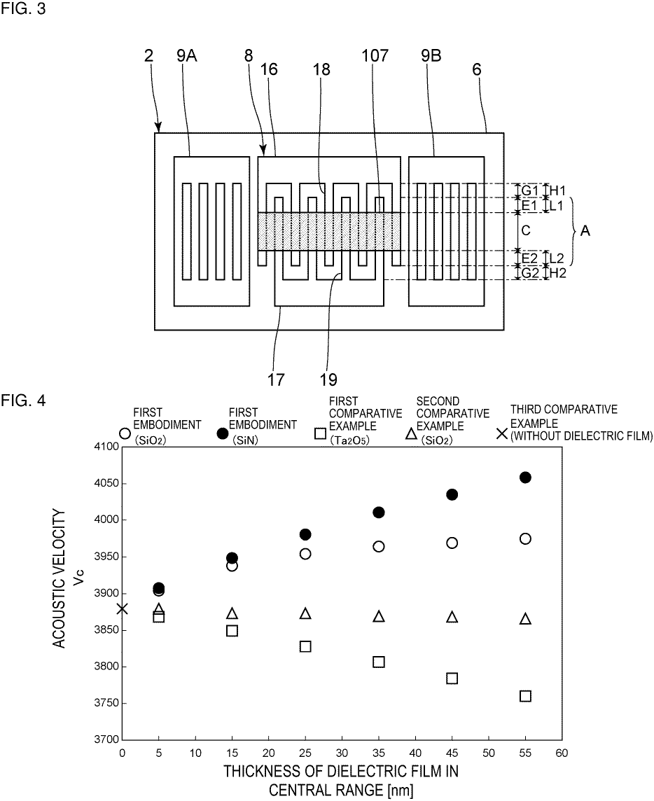

A relationship between an acoustic velocity in the central range and a thickness of the dielectric film in an acoustic wave device having a configuration similar to the first preferred embodiment and in a first comparative example and a second comparative example is examined. More specifically, the above relationship is examined in both cases where the dielectric film of the acoustic wave device having the configuration similar to the first preferred embodiment is a silicon oxide film and a silicon nitride film. In the first comparative example, a dielectric film provided at a position similar to the first preferred embodiment is a tantalum pentoxide film. Density of the tantalum pentoxide film is higher than density of a lithium tantalate layer as a piezoelectric layer. In the second comparative example, as illustrated in FIG. 3, a dielectric film 107 is provided to cover the IDT electrode 8. The dielectric film 107 is a silicon oxide film. Moreover, as a third comparative example, an acoustic velocity in the central range in a case without a dielectric film is examined. Design parameters of each acoustic wave device described above are as follows. Note that a wavelength defined by an electrode finger pitch of the IDT electrode is assumed as λ. The electrode finger pitch is a distance between centers of the respective electrode fingers next to each other.
Support substrate; material ... Si
High acoustic velocity film; material ... SiN, thickness ... about 300 nm
Low acoustic velocity film; material ... SiO₂, thickness ... about 300 nm
Piezoelectric layer; material ... 55° Y-cut LiTaO₃, thickness ... about 400 nm
IDT electrode; material of each layer ... Ti/Al/Ti from the piezoelectric layer side, thickness ... about 12 nm/100 nm/4 nm, wavelength λ ... about 2 µm, duty ratio ... about 0.5

Note that the thickness of each dielectric film is changed in increments of about 10 nm within a range of about 5 nm or larger and about 55 nm or smaller. In the third comparative example, the thickness of the dielectric film is zero.

FIG. 4 is a diagram illustrating a relationship between a thickness of a dielectric film and an acoustic velocity in a central range of an IDT electrode.

As illustrated in FIG. 4, in the first comparative example and the second comparative example, the acoustic velocity Vc in the central range decreases as the thickness of the dielectric film increases. As seen in the first comparative example, when the density of the dielectric film is higher than the density of the piezoelectric layer, the acoustic velocity Vc becomes lower even when the position and the thickness of the dielectric film is similar to the first preferred embodiment. As seen in the conventional example indicated by the second comparative example, the acoustic velocity Vc becomes lower also when the silicon oxide film is provided to cover the IDT electrode.

On the other hand, in the first preferred embodiment, the acoustic velocity Vc in the central range C increases as the thickness of the dielectric film 7 increases. Specifically, even when the silicon oxide film which is conventionally considered to lower the acoustic velocity is used, the acoustic velocity Vc can be increased. Therefore, as illustrated in FIG. 1, a difference in acoustic velocity between the central range C and the first and second ranges E1 and E2 can be provided, and a piston mode can be achieved. In this manner, a transverse mode can be suppressed while a degree of freedom in material is improved.

The reasons for this can be considered as follows. When the dielectric film 7 having low permittivity and density is provided between the piezoelectric layer 6 and the IDT electrode 8, intensity of electric field becomes lower, and an electromechanical coupling coefficient becomes smaller. Therefore, a fractional bandwidth becomes smaller, which is synonymous to a resonant frequency becoming higher. Assuming that the resonant frequency is f, the wavelength defined by the electrode finger pitch of the IDT electrode is λ, and the acoustic velocity is v, f = v/λ is established. Since the electrode finger pitch is constant and the wavelength λ is constant, the acoustic velocity v increases as the resonant frequency f becomes higher. Therefore, it can be said that when the dielectric film 7 having permittivity and density lower than those of the piezoelectric layer 6 is provided between the piezoelectric layer 6 and the IDT electrode 8, there is an effect to increase the acoustic velocity. It is described below that the resonant frequency becomes higher in the central range C in the first preferred embodiment. Moreover, the first preferred embodiment is compared with the case where the dielectric film 107 covers the IDT electrode 8 in the central range C, like the second comparative example.

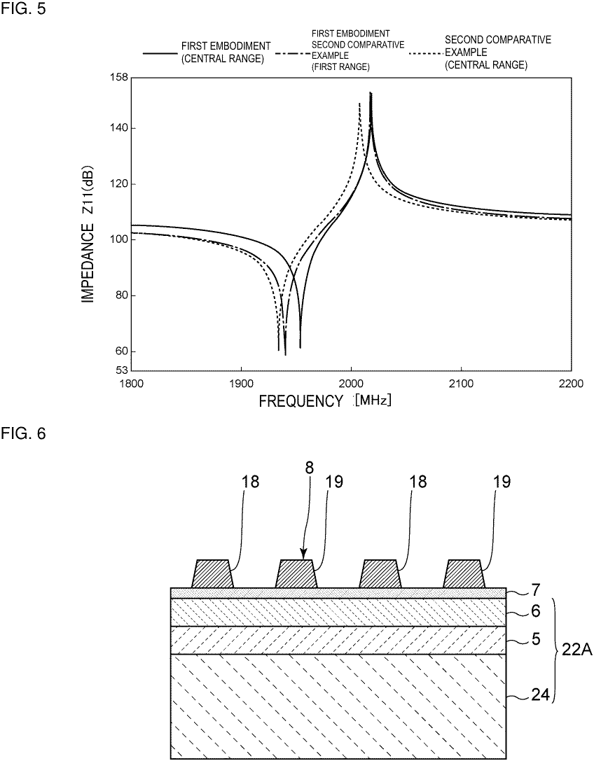

FIG. 5 is a diagram illustrating impedance frequency characteristics in the central range and the first range in the first preferred embodiment and the second comparative example. The configuration of the first range E1 is the same in the first preferred embodiment and the second comparative example. Thus, results regarding the first range E1 in the first preferred embodiment and the second comparative example are indicated by the same one-dot chain line.

As illustrated in FIG. 5, in the second comparative example, a resonant frequency in the central range C indicated by a broken line is lower than a resonant frequency in the first range E1 indicated by the one-dot chain line. Therefore, the acoustic velocity in the central range C is lower than the acoustic velocity in the first range E1, and a piston mode is not achieved.

On the other hand, in the first preferred embodiment, it can be seen that a resonant frequency in the central range C indicated by a solid line is higher than the acoustic velocity in the first range E1. Note that although not illustrated, a relationship between the acoustic velocities in the central range C and the second range E2 is also similar. As described above, in the first preferred embodiment and the second comparative example, the silicon oxide film is used as the dielectric film. Then, a piston mode is not achieved in the second comparative example whereas a piston mode can be achieved in the first preferred embodiment. In this manner, in the first preferred embodiment, a transverse mode can be suppressed while a degree of freedom in material is improved.

Meanwhile, as illustrated in FIG. 2, in the piezoelectric substrate 2, the high acoustic velocity film 4, the low acoustic velocity film 5, and the piezoelectric layer 6 are laminated in this order. Therefore, energy of an acoustic wave can effectively be confined on the piezoelectric layer 6 side. Note that the configuration of the piezoelectric substrate 2 is not limited to the above. A first modification and a second modification of the first preferred embodiment are described below in which only a configuration of the piezoelectric substrate is different from the first preferred embodiment. Also in the first modification and the second modification, similarly to the first preferred embodiment, a transverse mode can be suppressed while a degree of freedom in material is improved. Moreover, energy of an acoustic wave can effectively be confined on the piezoelectric layer 6 side.

In the first modification illustrated in FIG. 6, the high acoustic velocity material layer is a high acoustic velocity support substrate 24. A piezoelectric substrate 22A includes the high acoustic velocity support substrate 24, the low acoustic velocity film 5, and the piezoelectric layer 6. More specifically, the low acoustic velocity film 5 is provided on the high acoustic velocity support substrate 24. The piezoelectric layer 6 is provided on the low acoustic velocity film 5. Also in this modification, similarly to the first preferred embodiment, the piezoelectric layer 6 is indirectly provided on the high acoustic velocity material layer with the low acoustic velocity film 5 interposed therebetween.

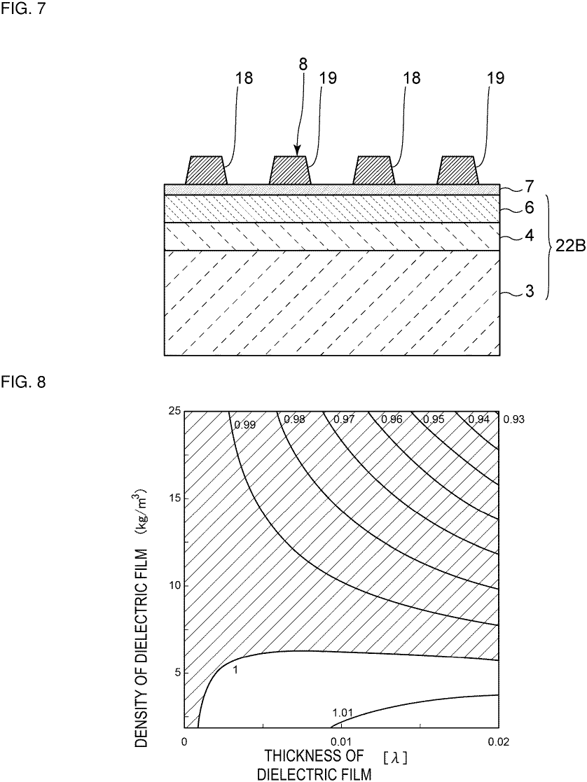

In the second modification illustrated in FIG. 7, a piezoelectric substrate 22B includes the support substrate 3, the high acoustic velocity film 4, and the piezoelectric layer 6. More specifically, the high acoustic velocity film 4 is provided on the support substrate 3. The piezoelectric layer 6 is provided on the high acoustic velocity film 4. In this modification, the piezoelectric layer 6 is directly provided on the high acoustic velocity material layer.

Note that the piezoelectric substrate may be a multilayer body of the high acoustic velocity support substrate 24 and the piezoelectric layer 6, or a multilayer body of the high acoustic velocity support substrate 24, the low acoustic velocity film 5, and the piezoelectric layer 6. Alternatively, the piezoelectric substrate may be a piezoelectric substrate defined only by the piezoelectric layer 6.

Here, in a case where the piezoelectric layer 6 is a lithium tantalate layer, the main electrode layer of the IDT electrode 8 is the Al layer, and the dielectric film 7 is made of an arbitrary dielectric, a relationship between each parameter of the acoustic wave device 1 and an acoustic velocity ratio Ve/Vc is examined. Note that the acoustic velocity ratio Ve/Vc is a ratio of the acoustic velocity Ve in the first range E1 and the second range E2 to the acoustic velocity Vc in the central range C. As the parameters described above, assume that the thickness of the dielectric film 7 is t_beta[λ], the permittivity of the dielectric film 7 is yuden, Young’s modulus of the dielectric film 7 is young[GPa], and the density of the dielectric film 7 is d_beta[kg/m³]. The acoustic velocity ratio Ve/Vc is measured while each of the t_beta, the yuden, the young, and the d_beta is changed. Design parameters of the measured acoustic wave device 1 are as follows.
Support substrate 3; material ... Si
High acoustic velocity film 4; material ... SiN, thickness ... about 300 nm
Low acoustic velocity film 5; material ... SiO₂, thickness ... about 300 nm
Piezoelectric layer 6; material ... 55° Y-cut LiTaO₃, thickness ... about 400 nm
IDT electrode 8; material of each layer ... Ti/Al/Ti from the piezoelectric layer 6 side, thickness ... about 12 nm/100 nm/4 nm, wavelength λ ... about 2 µm, duty ratio ... about 0.5

The relationship between each parameter and the acoustic velocity ratio Ve/Vc is examined based on the above measurement. The relationship between each parameter of the dielectric film 7 and the acoustic velocity ratio Ve/Vc is illustrated in FIGS. 8 to 10.

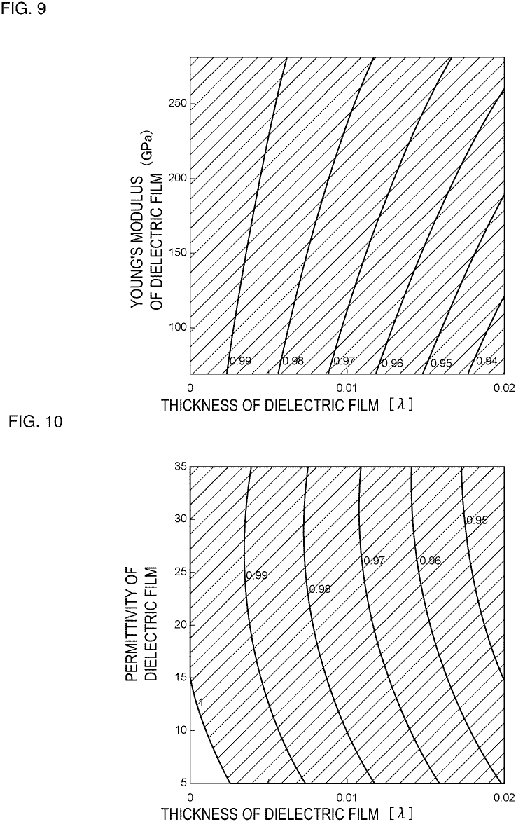

FIG. 8 is a diagram illustrating a relationship between the acoustic velocity ratio Ve/Vc and the thickness and density of the dielectric film. FIG. 9 is a diagram illustrating a relationship between the acoustic velocity ratio Ve/Vc and the thickness and Young’s modulus of the dielectric film. FIG. 10 is a diagram illustrating a relationship between the acoustic velocity ratio Ve/Vc and the thickness and permittivity of the dielectric film. Each curved line in FIGS. 8 to 10 indicates a relationship of the parameters where the acoustic velocity ratio Ve/Vc is constant.

A range indicated by hatching in FIGS. 8 to 10 is a range where Ve/Vc < 1 is established. A piston mode can certainly be achieved within these ranges. Therefore, by setting the value of each parameter of the used dielectric film 7 to fall within these ranges, a piston mode can more certainly be achieved, and a transverse mode can more certainly be suppressed.

Moreover, assume that a thickness of the piezoelectric layer 6 is t_LT[λ] and a thickness of the main electrode layer of the IDT electrode 8 is t_Al[λ]. The acoustic velocity ratio Ve/Vc is measured while each of the t_LT, the t_Al, the t_beta, the yuden, the young, and the d_beta is changed. Design parameters of the measured acoustic wave device 1 are as follows.
Support substrate 3; material ... Si
High acoustic velocity film 4; material ... SiN, thickness ... about 300 nm
Low acoustic velocity film 5; material ... SiO₂, thickness ... about 300 nm
Piezoelectric layer 6; material ... 55° Y-cut LiTaO₃, thickness ... t_LT
IDT electrode 8; material of each layer ... Ti/ Al/ Ti from the piezoelectric layer 6 side, thickness ... about 12 nm/t_Al/4 nm, wavelength λ ... about 2 µm, duty ratio ... about 0.5

The thickness t_beta of the dielectric film 7; changed in increments of about 0.0025 λ within a range of about 0.0025 λ or larger and about 0.0175 λ.

The permittivity yuden of the dielectric film 7; changed in increments of about 5 within a range of about 5 or higher and 35 or lower.

The Young’s modulus young of the dielectric film 7; changed in increments of about 70 GPa within a range of about 70 GPa or higher and about 280 GPa or lower.

The density d_beta of the dielectric film 7; changed in increments of about 2 kg/m³ within a range of 2 kg/m³ or higher and about 8 kg/m³ or lower.

The thickness t_LT of the piezoelectric layer 6; changed in increments of about 0.05 λ within a range of 0.15 λ or larger and about 0.3 λ or smaller.

The thickness t_Al of the main electrode layer of the IDT electrode; changed in increments of about 0.0125 λ within a range of about 0.05 λ or larger and about 0.075 λ.

Formula 1 which is a relational expression between each parameter and the acoustic velocity ratio Ve/Vc is derived based on the above measurement.

$$\begin{matrix}\text{Ve} / \text{Vc} = 1.00431413354797 + \left(- 0.00285716659280799\right) \\ \times \left(\text{d\_beta} \left[\text{kg} / {\text{m}}^{3}\right] - 4.66559485530547\right) + \\ 0.0000854138472667538 \\ \times \left(\text{young} \left[\text{GPa}\right] - 163.239549839228\right) + \\ \left(- 0.0003506253833567139\right) \\ \times \left(\text{yuden-20} \text{.050911039657}\right) + \\ 0.262088599487209 \\ \times \left(\text{t\_beta} \left[\text{λ}\right] - 0.00998794212218652\right) + \\ \left(- 0.00121829646867971\right) \\ \times \left(\text{t\_LT} \left[\text{λ}\right] - 0.29981243301179\right) + \left(- 0.0171813623903716\right) \\ \times \left(\text{tAl} \left[\text{λ}\right] - 0.064995980707398\right) + 0.0000011344571772174 \times \\ \left(\left(\text{d\_beta} \left[\text{kg} / {\text{m}}^{3}\right] - 4.66559485530547\right)\right) \\ \times \left(\left(\text{young} \left[\text{GPa}\right] - 163.239549839228\right)\right) + \\ \left(- 0.0000000938653776651\right) \times \\ \left(\left(\text{young} \left[\text{GPa}\right] - 163.239549839228\right)\right) \\ \times \left(\left(\text{young} \left[\text{GPa}\right] - 163.239549839228\right) \left(- 7625.27702101924\right)\right) + \\ 0.0000162006962167552 \\ \times \left(\left(\text{yuden-20} \text{.050911039657}\right) \times \left(\text{yuden-20} \text{.050911039657}\right)\right) - \\ \left(125.050998634098\right) + \left(- 0.286079428865232\right) \\ \times \left(\left(\text{d\_beta} \left[\text{kg} / {\text{m}}^{3}\right] - 4.66559485530547\right) \times \right) \\ \left(\left(\text{t\_beta} \left[\text{λ}\right] - 0.00998794212218652\right)\right) + 0.00817326864820186 \\ \times \left(\left(\text{young} \left[\text{GPa}\right] - 163.239549839228\right)\right) \times \\ \left(\left(\text{t\_beta} \left[\text{λ}\right] - 0.00998794212218652\right)\right) + \left(- 0.0221047213078\right) \\ \times \left(\left(\text{yuden-20} \text{.050911039657}\right) \times \right) \\ \left(\left(\text{t\_beta} \left[\text{λ}\right] - 0.00998794212218652\right)\right) + \left(- 17.2441046243263\right) \\ \times \left(\left(\text{t\_beta} \left[\text{λ}\right] - 0.00998794212218652\right)\right) \\ \times \left(\text{t\_beta} \left[\text{λ}\right] - 0.00998794212218652\right) - \\ \left(0.0000249563122710345\right) + 0.00438054956998946 \\ \times \left(\left(\text{d\_beta} \left[\text{kg} / {\text{m}}^{3}\right] - 4.66559485530547\right)\right) \times \\ \left(\left(\text{t\_LT} \left[\text{λ}\right] - 0.29981243301179\right)\right) + \left(- 0.000147617022443897\right) \\ \times \left(\left(\text{young} \left[\text{GPa}\right] - 163.239549839228\right)\right) \times \\ \left(\left(\text{t\_LT} \left[\text{λ}\right] - 0.29981243301179\right)\right) + \left(- 0.23034817620302\right) \\ \times \left(\left(\text{t\_beta} \left[\text{λ}\right] - 0.00998794212218652\right) \times \right) \\ \left(\left(\text{t\_LT} \left[\text{λ}\right] - 0.29981243301179\right)\right) + \left(0.0367578157483136\right) \\ \times \left(\left(\text{t\_LT} \left[\text{λ}\right] - 0.29981243301179\right)\right) \\ \times \left(\text{t\_LT} \left[\text{λ}\right] - 0.29981243301179\right) - \\ \left(0.0199865671766099\right) + 0.000409293299970899 \\ \times \left(\left(\text{young} \left[\text{GPa}\right] - 163.239549839228\right)\right) \times \\ \left(\left(\text{tAl} \left[\text{λ}\right] - 0.064995980707398\right)\right) + \left(- 1.89603355496479\right) \\ \times \left(\left(\text{t\_beta} \left[\text{λ}\right] - 0.00998794212218652\right) \times \right) \\ \left(\left(\text{tAl} \left[\text{λ}\right] - 0.064995980707398\right)\right) + \left(0.0528637488540428\right) \\ \times \left(\left(\text{t\_LT} \left[\text{λ}\right] - 0.29981243301179\right)\right) \times \\ \left(\left(\text{tAl} \left[\text{λ}\right] - 0.064995980707398\right)\right)\end{matrix} \qquad \text{(1)}$$

The acoustic velocity ratio Ve/Vc derived based on Formula 1 is preferably smaller than 1. More specifically, the values of the t_beta, the yuden, the young, the d_beta, the t_LT, and the t_Al preferably fall within a range where the acoustic velocity ratio Ve/Vc derived based on Formula 1 becomes smaller than 1. That is, the values of the thicknesses of the piezoelectric layer 6 and the main electrode layer of the IDT electrode 8 and each parameter of the dielectric film 7 are preferably set to fall within a range where the above conditions are satisfied. As a result, a piston mode can further certainly be achieved, and a transverse mode can further certainly be suppressed while a degree of freedom in material of the dielectric film 7 is improved.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer;
an IDT electrode provided on the piezoelectric substrate and including a plurality of electrode fingers; and
a dielectric film provided between the piezoelectric substrate and the IDT electrode; wherein
a portion of the IDT electrode in which the plurality of electrode fingers overlap with each other when seen in a propagation direction of an acoustic wave is an intersecting range, the plurality of electrode fingers being adjacent to each other, and when a direction in which the plurality of electrode fingers extend is an electrode finger extending direction, the intersecting range includes a central range located at a center in the electrode finger extending direction, and a first range and a second range sandwiching the central range in the electrode finger extending direction;
permittivity and density of the dielectric film are lower than permittivity and density of the piezoelectric layer; and
when seen in plan view, the dielectric film is provided at a portion overlapping with the central range, and not provided at a portion overlapping with one of the first range and the second range.

2. The acoustic wave device according to claim 1, wherein the dielectric film is a silicon oxide film, a silicon nitride film, or an aluminum oxide film.

3. The acoustic wave device according to claim 1, wherein
the piezoelectric substrate includes a high acoustic velocity material layer, and the piezoelectric layer is provided on the high acoustic velocity material layer; and
an acoustic velocity of a bulk wave that propagates in the high acoustic velocity material layer is higher than an acoustic velocity of an acoustic wave that propagates in the piezoelectric layer.

4. The acoustic wave device according to claim 3, wherein
the piezoelectric substrate includes a low acoustic velocity film provided between the high acoustic velocity material layer and the piezoelectric layer; and
an acoustic velocity of a bulk wave that propagates in the low acoustic velocity film is lower than an acoustic velocity of a bulk wave that propagates in the piezoelectric layer.

5. The acoustic wave device according to claim 3, wherein the high acoustic velocity material layer is a high acoustic velocity support substrate.

6. The acoustic wave device according to claim 3, wherein
the piezoelectric substrate includes a support substrate; and
the high acoustic velocity material layer is a high acoustic velocity film provided on the support substrate.

7. The acoustic wave device according to claim 1, wherein
the piezoelectric layer includes a lithium tantalate layer;
the IDT electrode includes a main electrode layer, and the main electrode layer is an Al layer; and
assuming that a wavelength defined by an electrode finger pitch of the IDT electrode is λ, a thickness of the dielectric film is t_beta[λ], the permittivity of the dielectric film is yuden, Young’s modulus of the dielectric film is young[GPa], the density of the dielectric film is d_beta[kg/m³], a thickness of the piezoelectric layer is t_LT[λ], a thickness of the main electrode layer of the IDT electrode is t_A1[λ], an acoustic velocity in the first range and the second range is Ve, and an acoustic velocity in the central range is Vc, values of the t_beta, the yuden, the young, the d_beta, the t_LT, and the t_Al fall within a range in which an acoustic velocity ratio Ve/Vc derived based on Formula 1 is smaller than 1:
$$\begin{matrix}\text{Ve} / \text{Vc} \text{=1} \text{.00431413354797+} \left(- 0.00285716659280799\right) \\ \times \left(\text{d\_beta} \left[\text{kg} / {\text{m}}^{3}\right] - 4.66559485530547\right) + \\ 0.0000854138472667538 \\ \times \left(\text{young} \left[\text{GPa}\right] - 163.239549839228\right) + \\ \left(- 0.0003506253833567139\right) \\ \times \left(\text{yuden} \text{−} \text{20} \text{.050911039657}\right) + 0.262088599487209 \\ \times \left(\text{t\_beta} \left[λ\right] - 0.00998794212218652\right) + \\ \left(- 0.00121829646867971\right) \\ \times \left(\text{t\_LT} \left[λ\right] - 0.29981243301179\right) + \left(- 0.0171813623903716\right) \\ \times \left(\text{t\_Al} \left[λ\right] - 0.064995980707398\right) + 0.0000011344571772174 \times \\ \left(\left(\text{d\_beta} \left[\text{kg} / {\text{m}}^{3}\right] - 4.66559485530547\right)\right) \\ \times \left(\left(\text{young} \left[\text{GPa}\right] - 163.239549839228\right)\right) \text{+} \\ \left(- 0.0000000938653776651\right) \times \left(\left(\text{young} \left[\text{GPa}\right] - 163.239549839228\right)\right) \\ \times \left(\left(\text{young} \left[\text{GPa}\right] - 163.239549839228\right) - 7625.27702101924\right) \\ + 0.0000162006962167552 \\ \times \left(\left(\text{yuden} \text{−} \text{20} \text{.050911039657}\right) \times \left(\text{yuden} \text{−} \text{20} \text{.050911039657}\right) - 125.050998634098\right) \\ + \left(- 0.286079428865232\right) \\ \times \left(\left(\text{d\_beta} \left[\text{kg} / {\text{m}}^{3}\right] - 4.66559485530547\right) \times \left(\text{t\_beta} \left[λ\right] - 0.00998794212218652\right)\right) \\ + 0.00817326864820186 \\ \times \left(\left(\text{young} \left[\text{GPa}\right] - 163.239549839228\right) \times \left(\text{t\_beta} \left[λ\right] - 0.00998794212218652\right)\right) \\ + \left(- 0.0221047213078\right) \\ \times \left(\left(\text{yuden} \text{−} \text{20} \text{.050911039657}\right) \times \left(\text{t\_beta} \left[λ\right] - 0.00998794212218652\right)\right) \\ + \left(- 17.2441046243263\right) \\ \times \left(\left(\text{t\_beta} \left[λ\right] - 0.00998794212218652\right)\right) \\ \times \left(\text{t\_beta} \left[λ\right] - 0.00998794212218652\right) - \left(0.0000249563122710345\right) \\ + 0.00438054956998946 \\ \times \left(\left(\text{d\_beta} \left[\text{kg} / {\text{m}}^{3}\right] - 4.66559485530547\right) \times \left(\text{t\_LT} \left[λ\right] - 0.29981243301179\right)\right) \\ + \left(- 0.000147617022443897\right) \\ \times \left(\left(\text{young} \left[\text{GPa}\right] - 163.239549839228\right) \times \left(\text{t\_LT} \left[λ\right] - 0.29981243301179\right)\right) \\ + \left(- 0.23034817620302\right) \\ \times \left(\left(\text{t\_beta} \left[λ\right] - 0.00998794212218652\right) \times \left(\text{t\_LT} \left[λ\right] - 0.29981243301179\right)\right) \\ + \left(- 0.0367578157483136\right) \\ \times \left(\left(\text{t\_LT} \left[λ\right] - 0.29981243301179\right)\right) \\ \times \left(\text{t\_LT} \left[λ\right] - 0.29981243301179\right) - \left(0.0199865671766099\right) \\ + 0.000409293299970899 \\ \times \left(\left(\text{young} \left[\text{GPa}\right] - 163.239549839228\right) \times \left(\text{t\_Al} \left[λ\right] - 0.064995980707398\right)\right) \\ + \left(- 1.89603355496479\right) \\ \times \left(\left(\text{t\_beta} \left[λ\right] - 0.00998794212218652\right) \times \left(\text{t\_Al} \left[λ\right] - 0.064995980707398\right)\right) \\ + \left(- 0.0528637488540428\right) \\ \times \left(\left(\text{t\_LT} \left[λ\right] - 0.29981243301179\right) \times \left(\text{t\_Al} \left[λ\right] - 0.064995980707398\right)\right)\end{matrix} \qquad \text{Formula 1}$$
.

8. The acoustic wave device according to claim 1, wherein the acoustic wave device is operable in a piston mode.

9. The acoustic wave device according to claim 1, wherein the piezoelectric substrate is a multilayer substrate.

10. The acoustic wave device according to claim 1, further comprising reflectors on both ends of the IDS electrode.

11. The acoustic wave device according to claim 1, wherein the piezoelectric layer is a lithium tantalate layer and the dielectric film is a silicon oxide film.

12. The acoustic wave device according to claim 1, wherein the piezoelectric layer includes lithium niobate, zinc oxide, aluminum nitride, crystal, or lead zirconate titanate.

13. The acoustic wave device according to claim 3, wherein the high acoustic velocity material layer includes silicon, aluminum oxide, silicon carbide, silicon nitride, silicon oxynitride, sapphire, lithium tantalate, lithium niobate, crystal, alumina, zirconia, cordierite, mullite, steatite, forsterite, magnesia, a diamond-like carbon film, or diamond.

14. The acoustic wave device according to claim 4, wherein the low acoustic velocity material layer includes glass, silicon oxide, silicon oxynitride, lithium oxide, or tantalum pentoxide, or a chemical compound in which fluorine, carbon, and boron are added to silicon oxide.

15. The acoustic wave device according to claim 1, wherein the piezoelectric substrate includes a support substrate including a piezoelectric material, a ceramic material, a dielectric material, a semiconductor material, or a resin material.

16. The acoustic wave device according to claim 1, wherein the IDT electrode includes a main electrode layer, an adhesion layer, and a protection layer.

17. The acoustic wave device according to claim 1, wherein the IDT electrode includes Ti layers and an Al layer.

18. The acoustic wave device according to claim 1, wherein the IDT electrode is defined only by a main electrode layer.
